(19) United States
(12) Patent Application Publication
(10) Pub. No.: US 2025/0308983 A1
(43) Pub. Date: Oct. 2, 2025

(54) SEMICONDUCTOR DEVICE AND FABRICATING METHOD THEREOF

(71) Applicant: Taiwan Semiconductor Manufacturing Company, Ltd., Hsinchu (TW)

(72) Inventors: Wen Hsiang Tu, Kaohsiung City (TW); Shuang-Ji Tsai, Tainan City (TW); Yen-Yu Chen, Kaohsiung City (TW); Yen-Ting Chiang, Tainan City (TW); Hsing-Chih Lin, Tainan City (TW); Jen-Cheng Liu, Hsin-Chu City (TW)

(73) Assignee: Taiwan Semiconductor Manufacturing Company, Ltd., Hsinchu (TW)

(21) Appl. No.: 18/624,149

(22) Filed: Apr. 2, 2024

(51) Int. Cl. H01L 21/762; H01L 21/308; H01L 27/146; H01L 29/06; H01L 29/66

(52) U.S. Cl. CPC H01L 21/76224; H01L 21/3086; H10D 62/115; H10D 64/021; H10F 39/807

(57) ABSTRACT

A semiconductor device and a manufacturing method thereof are provided. The semiconductor device includes a substrate, an etching stop structure, a passivation structure and an isolation structure. The etching stop structure is embedded in a front side of the substrate. The passivation structure is covering a backside of the substrate, and extending from the backside of the substrate to the etching stop structure within a trench of the substrate. The isolation structure is embedded in the trench of the substrate from the backside of the substrate. The passivation structure is located between the etching stop structure and of the isolation structure. The isolation structure has a first sidewall and a second sidewall unparallel to the first sidewall. The first sidewall is located between the second sidewall and a bottom surface of the isolation structure.

### BACKGROUND

Many modern electronic devices, such as smartphones, digital cameras, biomedical imaging devices, and automotive imaging systems, incorporate image sensors. These image sensors are configured to receive incident radiation and output corresponding electrical signals. The image sensor typically consists of one or more light detectors, such as photodiodes, phototransistors, or photoresistors. Two common types of image sensors are the Charge-Coupled Device (CCD) sensor and the Complementary Metal-Oxide-Semiconductor (CMOS) sensor. Compared to CCD sensors, CMOS sensors are favored for their low power consumption, compact size, fast data processing, direct data output, and lower manufacturing costs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A to FIG. 1S are schematic vertical cross-sectional views of intermediate structures that may be used to form an embodiment semiconductor device in accordance with various embodiments.

FIG. 2 is a schematic top view of a semiconductor device in accordance with various embodiments.

FIG. 3A to FIG. 3C are schematic vertical cross-sectional views of intermediate structures that may be used to form an embodiment semiconductor device in accordance with various embodiments.

FIG. 4 is a flow chart illustrating a method for fabricating the semiconductor device in accordance with some embodiments.

FIG. 5 is a schematic vertical cross-sectional view of a semiconductor device in accordance with various embodiments.

FIG. 6 is a schematic vertical cross-sectional view of a semiconductor device in accordance with various embodiments.

FIG. 7 is a schematic vertical cross-sectional view of a semiconductor device in accordance with various embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the structure in use or operation in addition to the orientation depicted in the figures. The apparatus may be otherwise oriented (rotated 90 degrees or at other orientations) and the spatially relative descriptors used herein may likewise be interpreted accordingly.

Many portable electronic devices, such as cameras and cellular telephones, incorporate image sensors for capturing images. One example of such an image sensor is a Complementary Metal-Oxide-Semiconductor (CMOS) image sensor (CIS), which features an array of pixels. Each pixel consists of at least one photodetector embedded in a semiconductor substrate. Additionally, the pixel may include a transfer gate designed to transfer accumulated charges from the photodetector to a floating diffusion node. To enhance electrical isolation between the photodetectors, a deep trench isolation (DTI) structure is strategically placed in the semiconductor substrate, surrounding the photodetectors.

For instance, in the semiconductor processing, the following steps are carried out: First, a trench is formed on a front side of a semiconductor substrate. Subsequently, within this trench, layers are sequentially deposited, including a sacrificial layer and an etching stop structure (or a contact etch stop layer, CESL). Next, the semiconductor substrate is flipped, and a backside of the semiconductor substrate is etched until the sacrificial layer in the trench is exposed. Following this, the sacrificial layer is selectively removed through an etching process. During the etching process, the etching stop structure within the trench prevents etchants from penetrating through the semiconductor substrate, thereby safeguarding components located on the front side of the semiconductor substrate. After removing the sacrificial layer, a passivation structure (or dielectric liner layer) and an isolation structure are sequentially formed within the trench.

In the semiconductor processing, when etching the backside of the semiconductor substrate, if the etching rate for the semiconductor substrate exceeds that of the sacrificial layer, protrusions may be formed around the sacrificial layer on the backside of the semiconductor substrate at the location where it is exposed. In the cross-sectional structure, the protrusions may contain sharp angles and may potentially lead to issues such as dark current (DC) and/or white pixel (WP). Additionally, the trench formed on the front side of the semiconductor substrate may exhibit a trapezoidal cross-section shape that is wider near the front side and narrower near the backside. The trapezoidal cross-section shape makes it challenging for the passivation structure and the isolation structure to be inserted from the backside into the trench (due to the small opening near the backside). In certain embodiments described herein, after etching the backside of the semiconductor substrate to expose the sacrificial layer, an additional etching process(es) is employed to enlarge the trench near the backside. This approach not only removes sharp angles that may cause DC and/or WP issues but also facilitates the subsequent insertion of the passivation structure and the isolation structure into the trench from the backside of the semiconductor substrate.

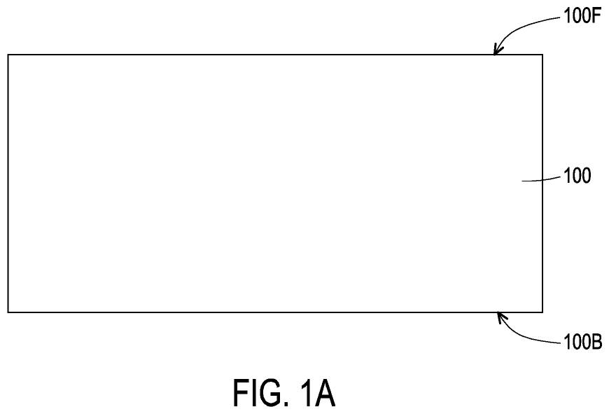

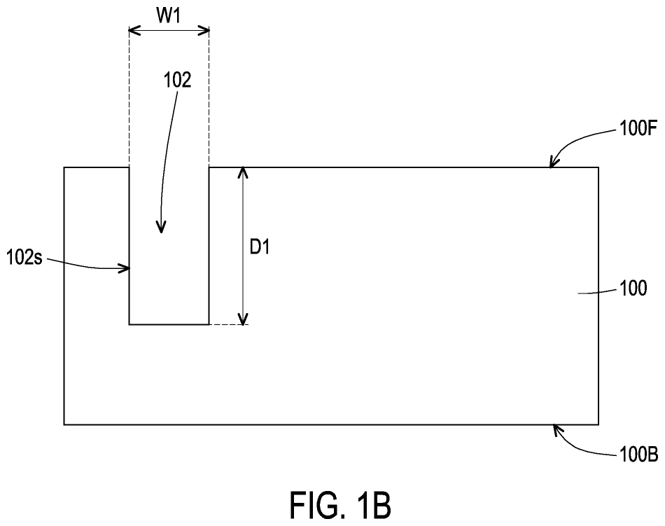

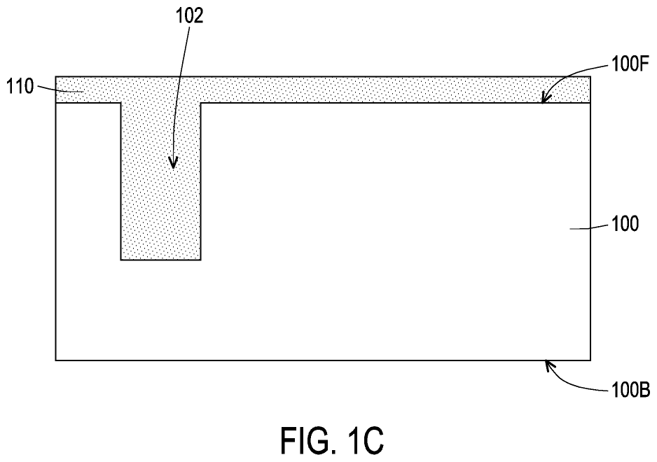

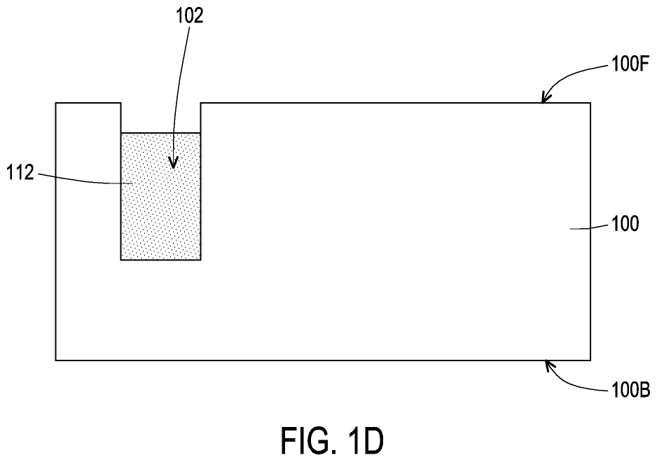

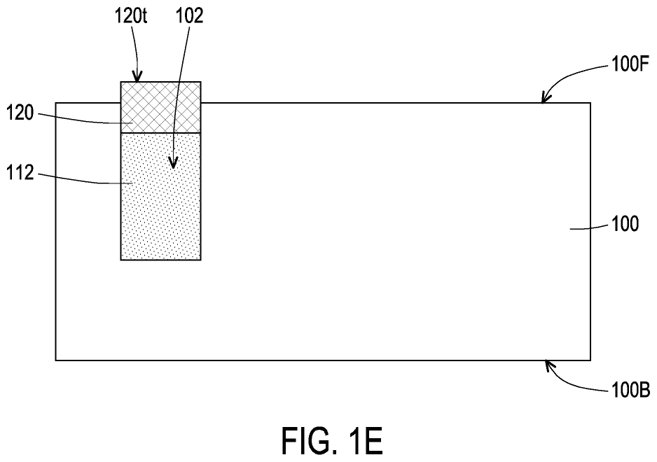

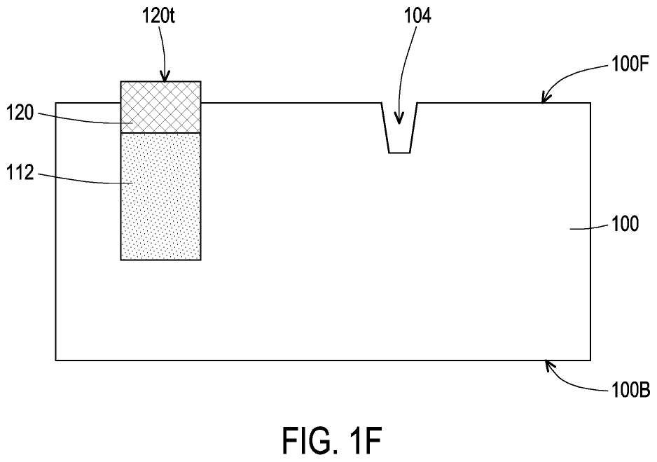

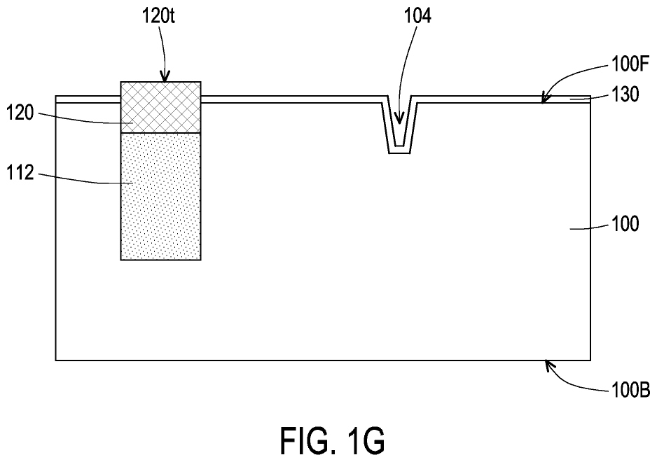

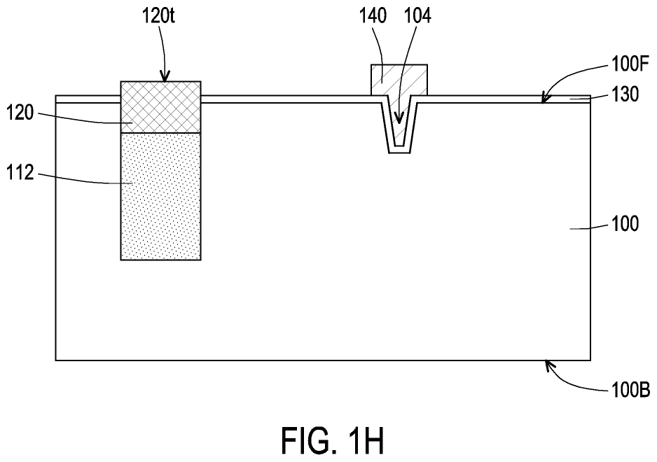

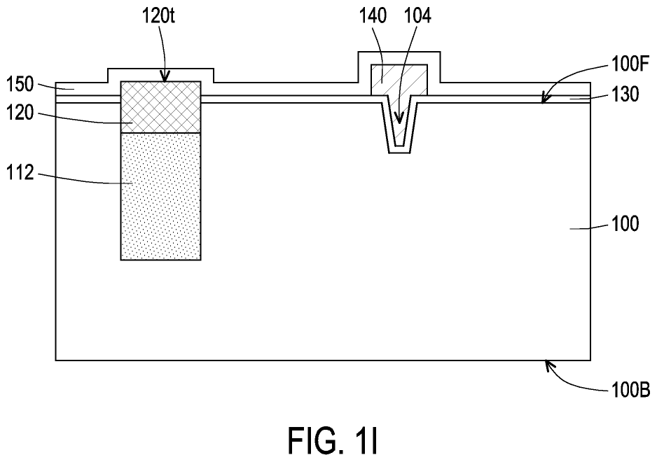

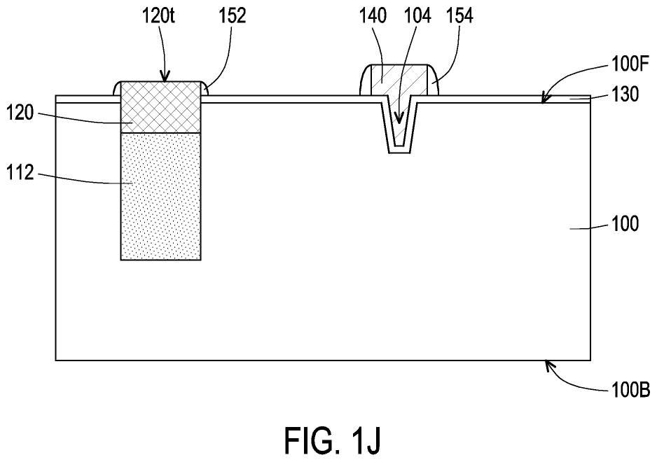

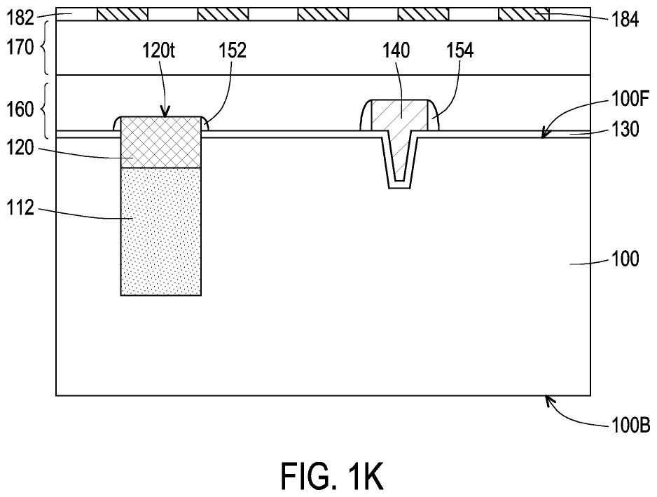

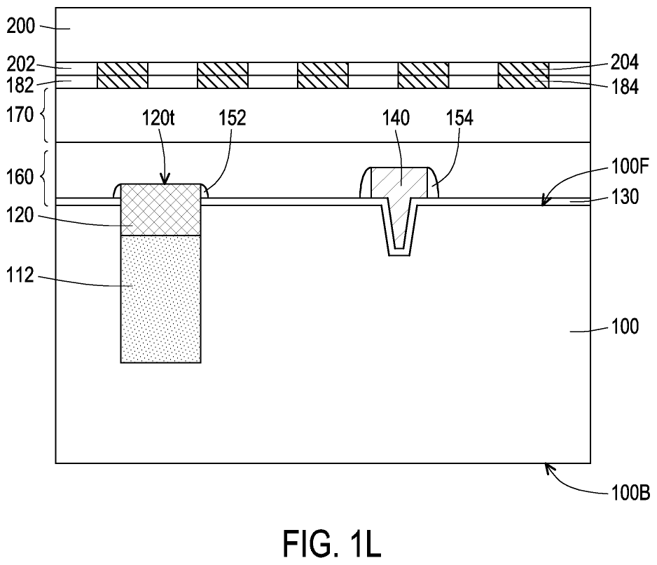

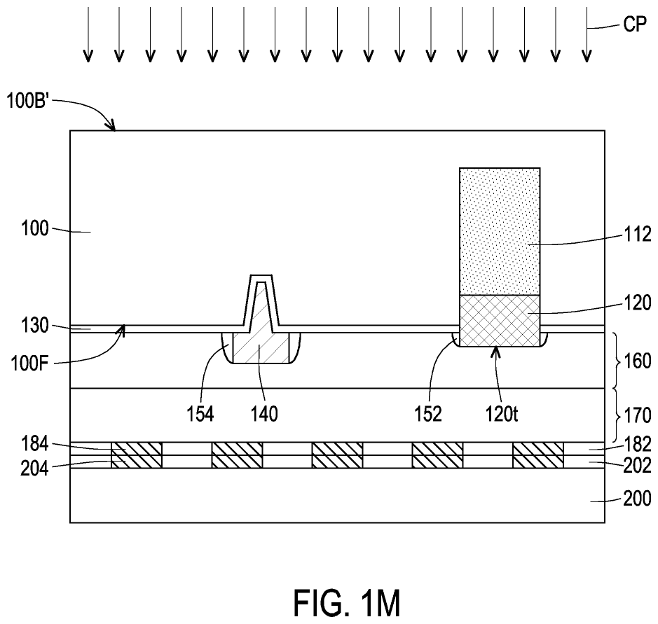

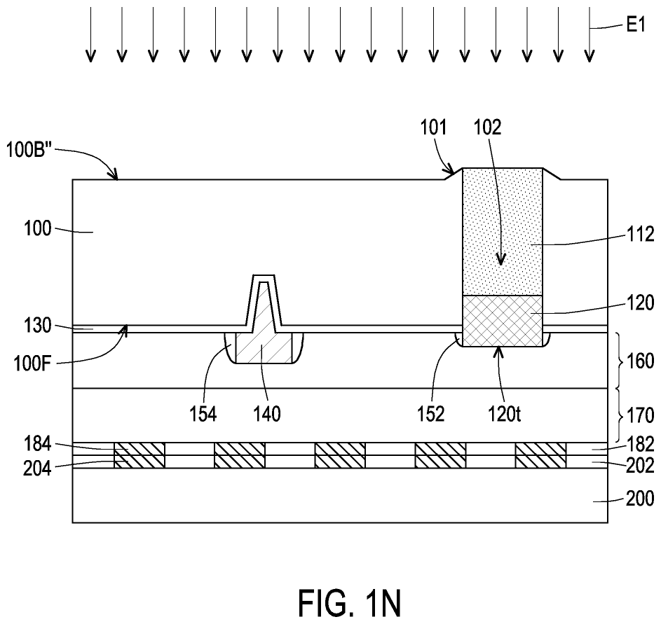

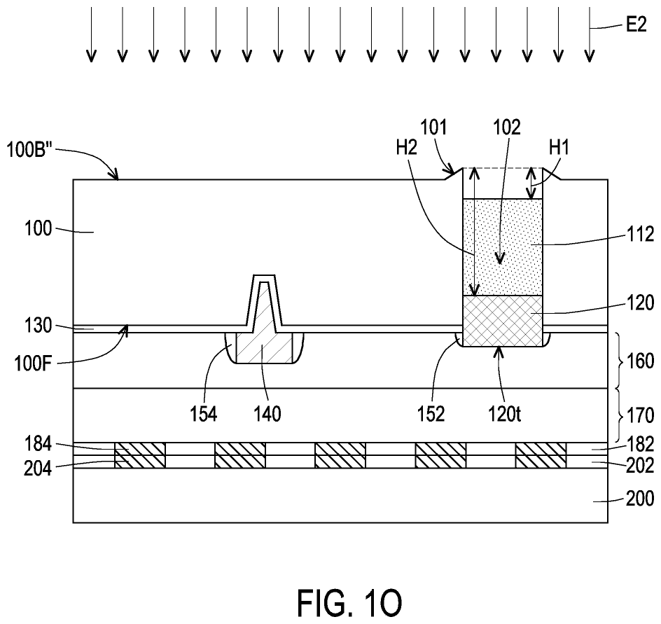

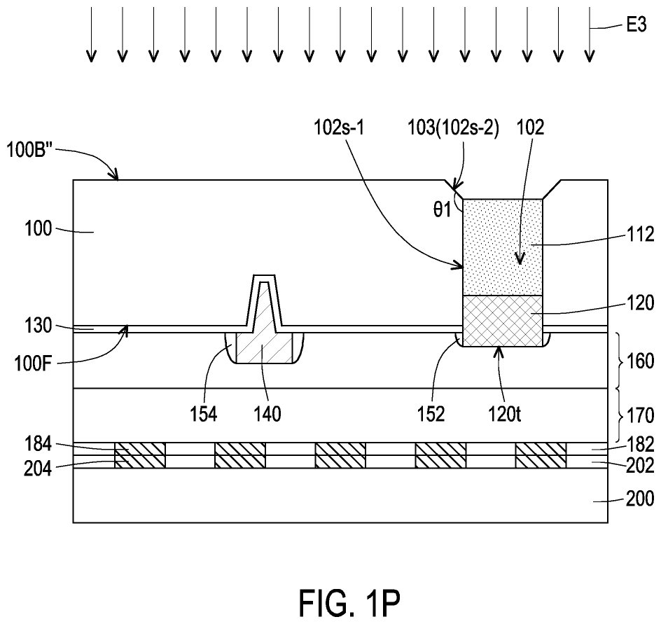

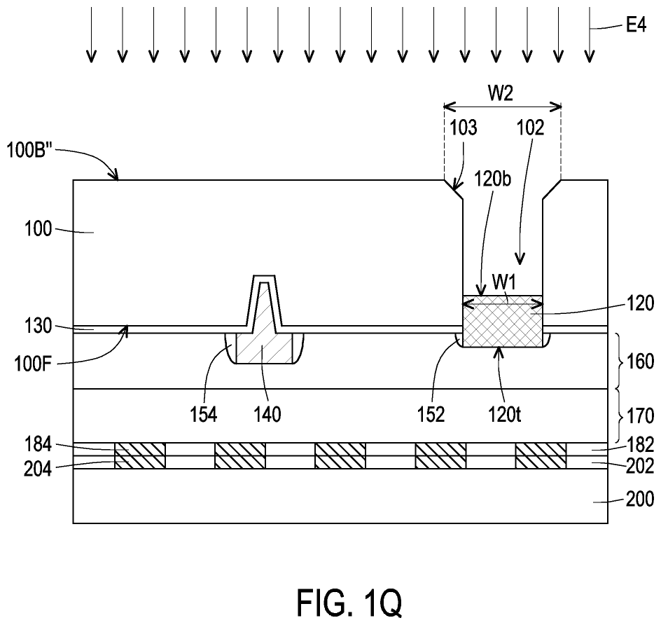

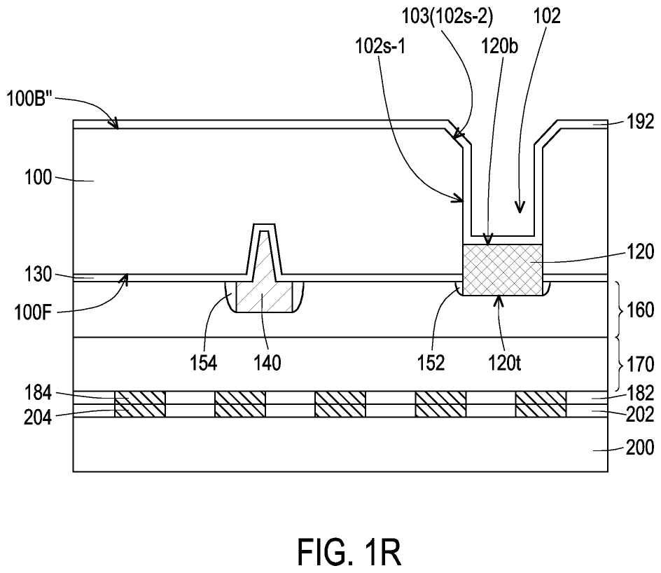

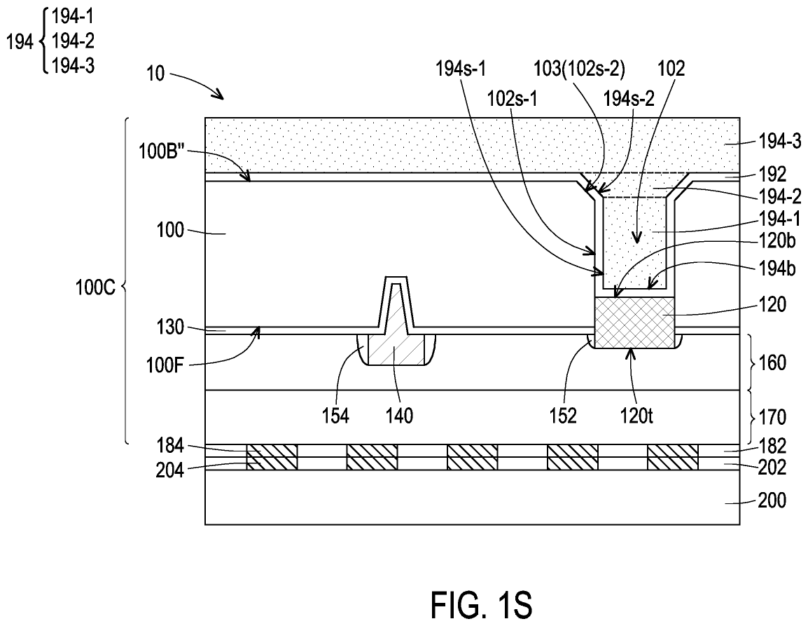

FIG. 1A to FIG. 1S are schematic vertical cross-sectional views of intermediate structures that may be used to form an embodiment semiconductor device 10 in accordance with various embodiments. Referring to FIG. 1A, a semiconductor substrate 100 is provided. The semiconductor substrate 100 has a first side 100F, also known as the front side, and a second side 100B, which corresponds to the backside and is opposite to the front side. The semiconductor substrate 100 may comprise any type of semiconductor body (e.g., monocrystalline silicon/CMOS bulk, silicon-germanium (SiGe), silicon on insulator (SOI), etc.).

Referring to FIG. 1B, a trench 102 is formed on the first side 100F of the semiconductor substrate 100. The etching process is performed on the first side 100F to form the trench 102. This etching process may be a dry etching process, such as a plasma etching process. During the plasma etching process, halogen-containing reactive gases are excited by an electromagnetic field, dissociating into ions. These reactive or etchant gases include CF₄, SF₆, NF₃, Cl₂, CCl₂F₂, SiCl₄, BCl₂, C₄F₈, HBr, O₂, N₂, or combinations thereof. Other semiconductor-material etchant gases are also considered within the scope of the present disclosure. Ions are accelerated to strike the exposed material using alternating electromagnetic fields or fixed bias, following established plasma etching methods.

Prior to the etching process, an etching mask (such as a hard mask) may be formed to define the size and location of the trench 102. The trench 102 itself may take various shapes, including trapezoidal, somewhat rectangular, or other suitable configurations. Depending on the etching parameters (such as radio frequency (RF) source power, bias power, electrode size, pressure, flow rate, etching duration, wafer temperature, and other relevant process parameters), the trench 102 may exhibit different profiles. For instance, at high power, the trench 102 tends to have vertical sidewalls. Conversely, at low power, the trench 102 tends to have sloped sidewalls. Additionally, when operating at low power, the upper sidewalls of the trench 102 may exhibit a curvature or arc. In some embodiments, the difference between the width of the top and the width of the bottom of the trench 102 falls within the range of 0 nm to 50 nm, for instance, 0 nm to 30 nm or 30 nm to 50 nm.

In some embodiments, the trench 102 has a substantially vertical sidewall 102s. In some embodiments, the width W1 of the trench 102 is in a range between 50 nm to 300 nm, and the depth D1 of the trench 102 is in a range between 3 μm to 6 μm.

Referring to FIG. 1C, a sacrificial material layer 110 is formed over the first side 100F of the semiconductor substrate 100 and filled into the trench 102. In some embodiments, the sacrificial material layer 110 may include silicon oxide, silicon nitride, silicon oxynitride, fluorine-doped silicate glass (FSG), boron silicate glass (BSG), phosphosilicate glass (PSG), organic materials, combinations thereof, and/or other suitable materials. In some embodiments, the sacrificial material layer 110 may include a low-k dielectric material, such as a dielectric material having a dielectric constant that is less than 3.9. In various examples, the sacrificial material layer 110 may be deposited by a chemical vapor deposition (CVD) process, a flowable CVD (FCVD) process, spin-on coating, a high-density plasma CVD (HDPCVD) process, and/or other suitable process.

Referring to FIG. 1D, an etching process, such as an etching back process, is performed to pattern the sacrificial material layer 110, resulting in the formation of the sacrificial layer 112 within the trench 102. In some embodiments, the sacrificial layer 112 does not completely fill the trench 102.

Referring to FIG. 1E, an etching stop structure 120 is formed above the sacrificial layer 112 within the trench 102. The etching stop structure 120 is embedded in the first side 100F of the semiconductor substrate 100. The etching stop structure 120 and the sacrificial layer 112 consist of different materials. For instance, the sacrificial layer 112 comprises silicon oxide. In contrast, the etching stop structure 120 comprises silicon nitride. In certain embodiments, the process involves initially depositing a dielectric material (such as silicon nitride) over the first side 100F of the semiconductor substrate 100 and in the trench 102. Subsequently, the deposited dielectric material is patterned to form the etching stop structure 120.

In some embodiments, a top surface 120t of the etching stop structure 120 is protruding from the first side 100F of the semiconductor substrate 100, but the disclosure is not limited thereto. In other embodiments, a top surface 120t of the etching stop structure 120 is coplanar with or lower than the first side 100F of the semiconductor substrate 100.

Referring to FIG. 1F, a recess 104 is optionally formed on the first side 100F of the semiconductor substrate 100. In some embodiments, a depth of the recess 104 is less than the depth of the trench 102.

Referring to FIG. 1G, a dielectric layer 130 is conformally formed on the first side 100F of the semiconductor substrate 100 and in the recess 104. In some embodiments, the dielectric layer 130 does not cover the top surface 120t of the etching stop structure 120, but the disclosure is not limited thereto. In other embodiments, the dielectric layer 130 covers a sidewall and the top surface 120t of the etching stop structure 120. In some embodiments, the dielectric layer 130 is or comprises, for example, an oxide (e.g., silicon dioxide (SiO₂)), a high-k dielectric material (e.g., hafnium oxide (HfO), tantalum oxide (TaO), hafnium silicon oxide (HfSiO), hafnium tantalum oxide (HfTaO), aluminum oxide (AlO), zirconium oxide (ZrO), some other dielectric material with a dielectric constant greater than about 3.9), some other dielectric material, or a combination of the foregoing. The dielectric layer 130 may be deposited by, for example, thermal oxidation, CVD, physical vapor deposition (PVD), atomic layer deposition (ALD), a spin-on process, some other deposition process, or a combination of the foregoing.

Referring to FIG. 1H, a gate electrode 140 (e.g. a transfer gate) is formed over the first side 100F of the semiconductor substrate 100 and in the recess 104. In some embodiments, the method for forming the gate electrode 140 involves the following steps: Deposition of a conductive material (such as polycrystalline silicon, metal, or other suitable materials) onto the dielectric layer 130. Subsequently, the deposited conductive material is patterned to form the gate electrode 140. In some embodiments, the dielectric layer 130 is selectively etched to ensure alignment between the dielectric layer 130 and the gate electrode 140. In other words, the sidewall of the dielectric layer 130 may aligned with the sidewall of the gate electrode 140.

Referring to FIG. 1I, a spacer material layer 150 is formed over the dielectric layer 130, the gate electrode 140 and the etching stop structure 120. In some embodiments, the spacer material layer 150 may be or comprise, for example, a nitride (e.g., SiN), an oxynitride (e.g., SiOₓN_{y}), an oxide (e.g., SiO₂), a carbide (e.g., silicon carbide (SiC)), some other dielectric material, or a combination of the foregoing (e.g., oxide-nitride-oxide multilayer structure). In some embodiments, a process for forming the spacer material layer 150 comprises depositing or growing the spacer material layer 150 on the semiconductor substrate 100 and on the gate electrode 140. In further embodiments, the spacer material layer 150 may be deposited or grown by, for example, CVD, PVD, ALD, sputtering, thermal oxidation, some other deposition or growth process, or a combination of the foregoing. In some embodiments, the spacer material layer 150 may be formed as a conformal layer.

Referring to FIG. 1J, the spacer material layer 150 is etched to form a first spacer 152 surrounding the etching stop structure 120 and a second spacer 154 surrounding the gate electrode 140. In some embodiments, the first spacer 152 is disposed on the sidewall of the etching stop structure 120, and the second spacer 154 is disposed on the sidewall of the gate electrode 140. The etching process removes unmasked horizontal portions of spacer material layer 150, thereby leaving vertical portions of the spacer material layer 150 in place as the first spacer 152 and the second spacer 154. In some embodiments, the etching process may be or comprise, for example, a wet etching process, a dry etching process, a RIE process, some other etching process, or a combination of the foregoing.

In some embodiments, a height of the etching stop structure 120 protruding the first side 100F of the semiconductor substrate 100 is different than that of the gate electrode 140. Therefore, a height of the first spacer 152 is different from a height of the second spacer 154.

Referring to FIG. 1K, an inter-layer dielectric (ILD) structure 160 is formed over the etching stop structure 120 and the gate electrode 140. The ILD structure 160 is formed over the first side 100F of the semiconductor substrate 100. In some embodiments, a plurality of conductive contacts (not shown in FIG. 1K) are embedded in the ILD structure 160 and over the first side 100F of the semiconductor substrate 100.

A redistribution layer (RDL) 170 is formed over the ILD structure 160. In some embodiments, the RDL 170 includes a dielectric layer having redistribution structures, such as metal lines and/or vias, embedded therein. In some embodiments, a bonding dielectric 182 and metal pads 184 used for hybrid bond process may be formed over/in the RDL 170.

Referring to FIG. 1L, the RDL 170 is bonded to an integrated circuit 200 (e.g. an application-specific integrated circuit (ASIC) or other integrated circuit) by hybrid bonding. The hybrid bonding process including the dielectric-to-dielectric direct bonds between the bonding dielectric 182 and the bonding dielectric 202 and metal-to-metal direct bonds between the metal pads 204 and the metal pads 184. In some embodiments, the bonding of the structure shown in FIG. 1L may be performed at a wafer-to-wafer level or a die-to-wafer level.

Referring to FIG. 1M, the semiconductor substrate 100 is flipped. Then, a thinning process CP is performed to thin the semiconductor substrate 100 from the second side 100B by, for example, a mechanical grinding process and/or a chemical mechanical polishing (CMP) process, or other applicable processes. In some embodiments, the second side 100B′ after the thinning process CP is separated from the sacrificial layer 112.

Referring to FIG. 1N, a first etching process E1 is carried out on the second side 100B′ of the semiconductor substrate 100 to expose the sacrificial layer 112. In certain embodiments, this first etching process E1 may be either a wet etching process, a dry etching process, or a combination of both. In some embodiments, the dry etching processes may generate sputtered residues, potentially contaminating the semiconductor substrate 100. To mitigate this issue, it is advisable to precede the dry etching process with a wet etching step. This approach reduces the time required for the subsequent dry etching process and helps avoid the aforementioned contamination concerns. Alternatively, in some cases, the dry etching process may be omitted altogether.

As a result of the distinct etching rates between the semiconductor substrate 100 and the sacrificial layer 112, protrusions may emerge around the exposed sacrificial layer 112. These protrusions exhibit a sharp corner 101 at their uppermost points. In some embodiments, the first etching process E1 contributes to the formation of these sharp corners 101 on the second side 100B″ of the semiconductor substrate 100, particularly around the trench 102.

Referring to FIG. 1O, a second etching process E2 is performed to remove a portion of the sacrificial layer 112 in the trench 102. The second etching process E2 may be either a wet etching process, a dry etching process, or a combination of both. In some embodiments, the height H1 of the portion of the sacrificial layer 112 that is removed by the second etching process E2 is 5% to 30% of a total height H2 of the original sacrificial layer 112. In other words, after the second etching process E2, 70% to 95% of the sacrificial layer 112 is still retained in the trench 102.

Referring to FIG. 1P, a third etching process E3 is performed to remove the sharp corners 101 of the semiconductor substrate 100 around the trench 102. The third etching process E3 may be a wet etching process.

A chamfer 103 is formed at the corner of a sidewall of the trench 102 and the second side 100B″ of the semiconductor substrate 100. Specifically, after the third etching process E3, a portion of the sidewall of the trench 102 that is not shielded by the sacrificial layer 112 extends outward, resulting in the formation of the chamfer 103. In other words, following the third etching process E3, the sidewall of the trench 102 comprises the first side surface 102s-1 and the second side surface 102s-2, forming an angle θ1 between them. In some embodiments, the angle θ1 is in a range between 100 degrees and 170 degrees.

In some embodiments, the portion of the sacrificial layer 112 in the trench 102 protects a portion of a sidewall 102 (i.e. the first side surface 102s-1) of the trench 102 during the third etching process E3. Therefore, the lateral expansion of the trench 102 may be avoided. In certain embodiments, in addition to the sidewall of the trench 102 being etched during the third etching process E3, the second side 100B″ of the semiconductor substrate 100 may also undergo etching. That is, the third etching process E3 may further thin the semiconductor substrate 100.

Referring to FIG. 1Q, a fourth etching process E4 is performed to remove the remained portion of the sacrificial layer 112 in the trench 102, thereby exposing a bottom surface 120b of the etching stop structure 120 in the trench 102. The fourth etching process E4 may be either a wet etching process, a dry etching process, or a combination of both.

In certain embodiments, during the third etching process E3 (as shown in FIG. 1P), the width W2 of the trench 102 at the second side 100B″ is expanded. Consequently, the width W2 of the trench 102 at the second side 100B″ becomes greater than the width W1 of the trench 102 at the first side 100F. This deliberate widening facilitates the subsequent deposition of materials, making it easier for them to enter the trench 102 from the second side 100B″.

Referring to FIG. 1R, a passivation structure 192 (i.e. an insulation layer) is formed over the second side 100B″ of the semiconductor substrate 100, and extending from the second side 100B″ to a bottom surface 120b of the etching stop structure 120 along the second side surface 102s-2 and the first side surface 102s-1. The passivation structure 192 may conformally line the trench 102.

The passivation structure 192 may include a single-layered structure or a multi-layered structure. In some embodiments, the passivation structure 192 is or comprises aluminum oxide, hafnium oxide, tantalum oxide or combinations thereof. The passivation structure 192 may be deposited by, for example, CVD, PVD, ALD, a spin-on process, some other deposition process, or a combination of the foregoing.

Referring to FIG. 1S, an isolation structure 194 is formed over the passivation structure 192 and in the trench 102. The passivation structure 192 is located between the bottom surface 120b of the etching stop structure 120 and a bottom surface 194b of the isolation structure 194.

In some embodiments, the isolation structure 194 may include silicon oxide, silicon nitride, silicon oxynitride, FSG, BSG, PSG, organic materials, combinations thereof, and/or other suitable materials. In some embodiments, the isolation structure 194 may include a low-k dielectric material, such as a dielectric material having a dielectric constant that is less than 3.9. In various examples, the isolation structure 194 may be deposited by CVD process, FCVD process, spin-on coating, HDPCVD process, and/or other suitable process.

In this embodiment, the isolation structure 194 filled within the trench 102 may also be referred to as a deep trench isolation (DTI) structure. The DTI structure is embedded in the second side 100B″ of the semiconductor substrate 100, overlapping with the etching stop structure 120. The isolation structure 194 comprises a first portion 194-1, a second portion 194-2 and a third portion 194-3. Both the first portion 194-1 and the second portion 194-2 are embedded within the semiconductor substrate 100, collectively constituting the DTI structure. The third portion 194-3 is disposed over the second side 100B″ of the semiconductor substrate 100. The second portion 194-2 is connected between the first portion 194-1 and the third portion 194-3. The first portion 194-1 is located between the etching stop structure 120 and the second portion 194-2.

A width of the second portion 194-2 is greater than a width of the first portion 194-1. The first portion 194-1 has a first sidewall 194s-1, and the second portion 194-2 has a second sidewall 194s-2 unparallel to the first sidewall 194s-1. The first side surface 102s-1 and the second side surface 102s-2 of the trench 102 respectively facing to the first sidewall 194s-1 and the second sidewall 194s-2 of the isolation structure 194. The passivation structure 192 is located between the first sidewall 194s-1 and the semiconductor substrate 100 and between the second sidewall 194s-2 and the semiconductor substrate 100. The first sidewall 194s-1 is located between the second sidewall 194s-2 and the bottom surface 194b of the isolation structure 194. In some embodiments, a slope of the first sidewall 194s-1 is different from (greater than or less than) a slope of the second sidewall 194s-2.

The structure 100C, which includes the DTI structure, may represent a System on Chip (SoC) structure. Additionally, the semiconductor device 10 comprises both the SoC structure and an integrated circuit 200 (such as an ASIC) bonded together. Furthermore, in some embodiments, additional components such as a metal grid, color filter, or lens may be formed over the isolation structure 194, although the disclosure is not limited thereto.

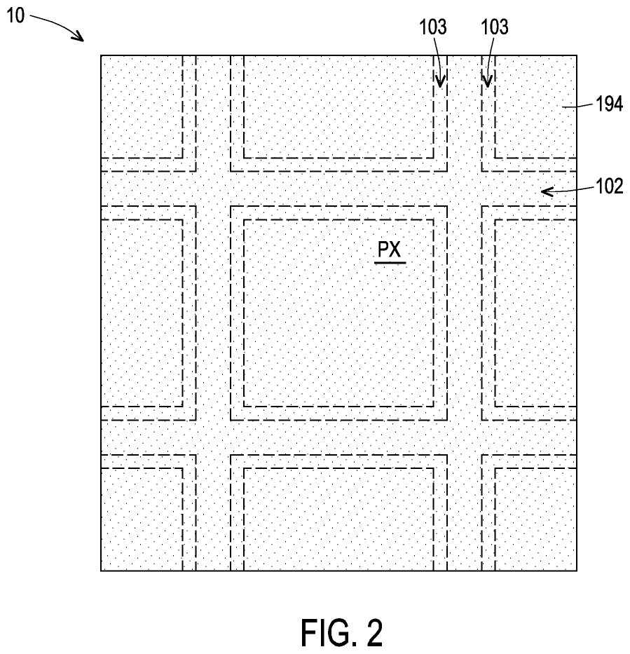

FIG. 2 is a schematic top view of the semiconductor device 10 in accordance with various embodiments. The trench 102, along with the embedded DTI structure, effectively separates multiple pixel regions PX from each other. Each pixel region PX may contain one or more photodiodes embedded in the semiconductor substrate.

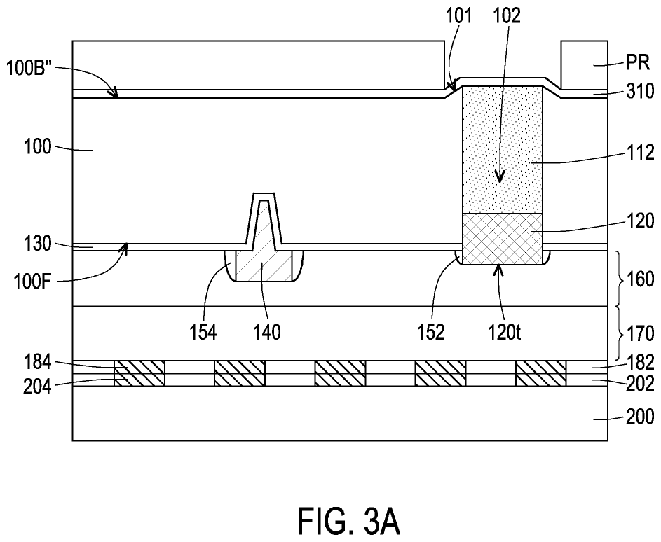

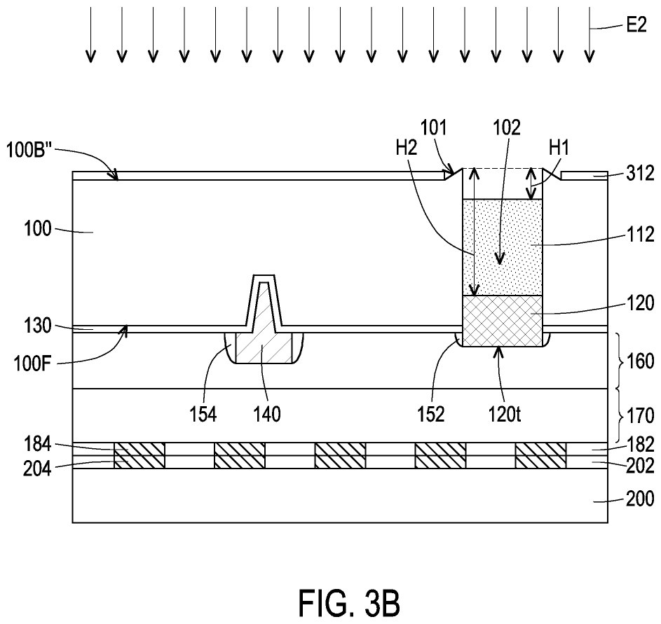

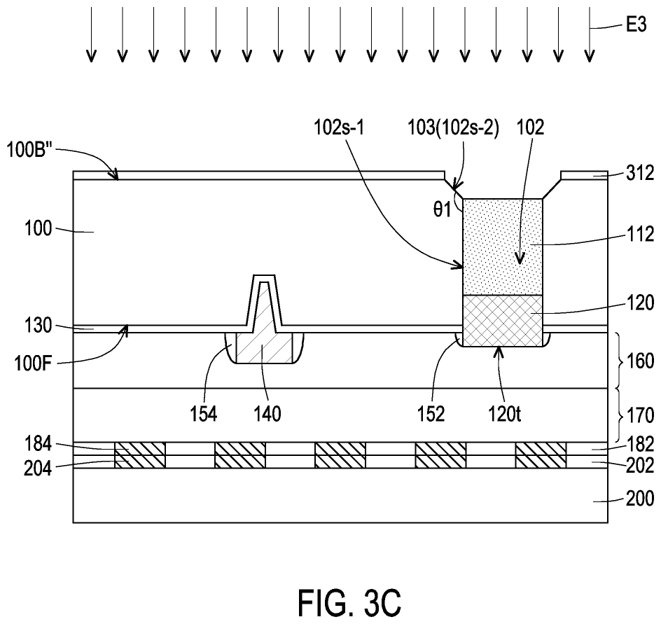

FIG. 3A to FIG. 3C are schematic vertical cross-sectional views of intermediate structures that may be used to form an embodiment semiconductor device in accordance with various embodiments. It should be noted herein that, in embodiments provided in FIG. 3A to FIG. 3C, element numerals and partial content of the embodiments provided in FIG. 1A to FIG. 1S are followed, the same or similar reference numerals being used to represent the same or similar elements, and description of the same technical content being omitted. For a description of an omitted part, reference may be made to the foregoing embodiment, and the descriptions thereof are omitted herein.

Referring to FIG. 3A, after the step shown in FIG. 1N, a hard mask material layer 310 is formed over the second side 100B″, the sharp corner 101 and the sacrificial layer 112. In some embodiments, the hard mask material layer 310 and the sacrificial layer 112 include the same or different materials. In some embodiments, the hard mask material layer 310 and the sacrificial layer 112 are both oxides.

A patterned photoresist layer PR is formed over the hard mask material layer 310. The patterned photoresist layer PR has an opening overlapping with the sharp corner 101 and the sacrificial layer 112.

In FIG. 3B, the hard mask material layer 310 is patterned using the patterned photoresist layer PR as a mask, resulting in the formation of the hard mask layer 312. The hard mask layer 312 exposes both the sharp corner 101 and the sacrificial layer 112.

In some embodiments, the hard mask material layer 310 and the sacrificial layer 112 consist of similar materials. Consequently, during the second etching process E2, it is possible to simultaneously pattern the hard mask material layer 310 and remove a portion of the sacrificial layer 112 within the trench 102. The second etching process E2 may be either a wet etching process, a dry etching process, or a combination of both. In some embodiments, the height H1 of the portion of the sacrificial layer 112 that is removed by the second etching process E2 is 5% to 30% of a total height H2 of the original sacrificial layer 112. In other words, after the second etching process E2, 70% to 95% of the sacrificial layer 112 is still retained in the trench 102.

In other embodiments, the hard mask material layer 310 and the sacrificial layer 112 are composed of different materials. Consequently, the patterning of the hard mask material layer 310 and the removal of a portion of the sacrificial layer 112 are accomplished using distinct etching processes.

Referring to FIG. 3C, a third etching process E3 is performed to remove the sharp corners 101 of the semiconductor substrate 100 around the trench 102. The third etching process E3 may be a wet etching process.

A chamfer 103 is formed at the corner of a sidewall of the trench 102 and the second side 100B″ of the semiconductor substrate 100. Specifically, after the third etching process E3, a portion of the sidewall of the trench 102 that is not shielded by the sacrificial layer 112 extends outward, resulting in the formation of the chamfer 103. In other words, following the third etching process E3, the sidewall of the trench 102 comprises the first side surface 102s-1 and the second side surface 102s-2, forming an angle θ1 between them. In some embodiments, the angle θ1 is in a range between 100 degrees and 170 degrees.

In this embodiment, the hard mask layer 312 serves to protect the second side 100B″ of the semiconductor substrate 100, thereby preventing the semiconductor substrate from thinning during the third etching process E3.

Following the FIG. 3C, the processes depicted in FIG. 1Q to FIG. 1S are executed to form the semiconductor device 10. In some embodiment, since the hard mask layer 312 and the sacrificial layer 112 consist of similar materials, both the hard mask layer 312 and the remaining sacrificial layer 112 within the trench 102 may be removed together by the fourth etching process E4, as shown in FIG. 1Q. In other embodiments, the hard mask layer 312 and the sacrificial layer 112 consist of different materials, and are removed using distinct etching processes.

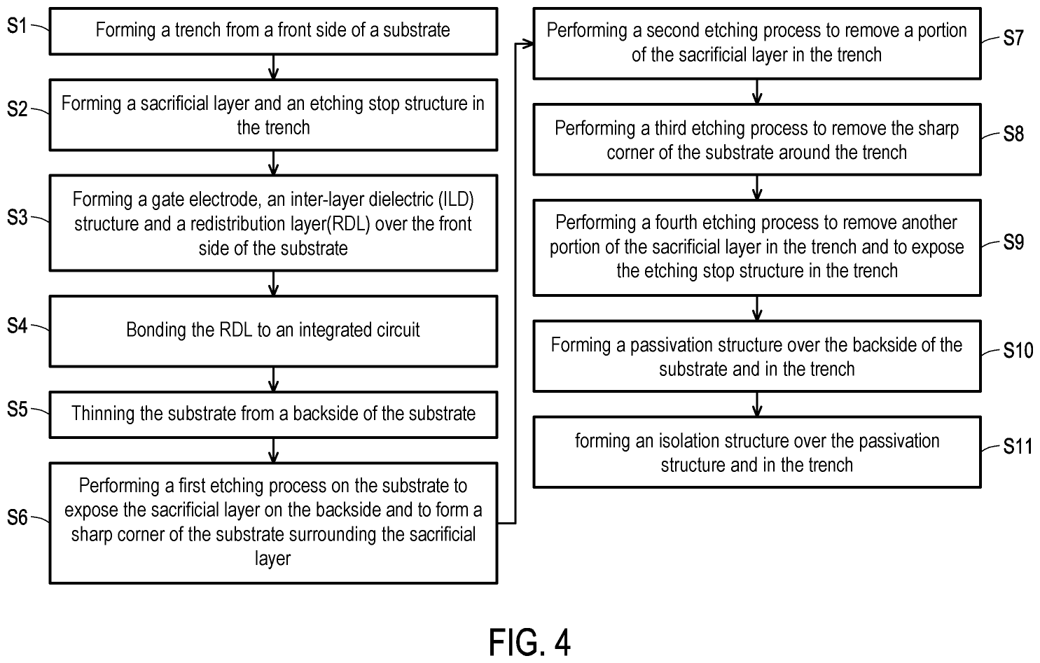

FIG. 4 is a flow chart illustrating a method for fabricating the semiconductor device in accordance with some embodiments. Referring to FIG. 1A, FIG. 1B, and FIG. 4, in step S1, a trench is formed from a front side of a substrate.

Referring to FIG. 1C to 1E, and FIG. 4, in step S2, a sacrificial layer and an etching stop structure are formed within the trench.

Referring to FIG. 1F to 1K, and FIG. 4, in step S3, a gate electrode, an inter-layer dielectric (ILD) structure and a redistribution layer (RDL) are formed over the front side of the substrate.

Referring to FIG. 1L, and FIG. 4, in step S4, the RDL is bonded to an integrated circuit.

Referring to FIG. 1M, and FIG. 4, in step S5, the substrate is thinned from a backside of the substrate.

Referring to FIG. 1N, and FIG. 4, in step S6, a first etching process is performed on the substrate to expose the sacrificial layer on the backside and to form a sharp corner of the substrate surrounding the sacrificial layer.

Referring to FIG. 1O, and FIG. 4, in step S7, a second etching process is performed to remove a portion of the sacrificial layer in the trench.

Referring to FIG. 1P, and FIG. 4, in step S8, a third etching process is performed to remove the sharp corner of the substrate around the trench.

Referring to FIG. 1Q, and FIG. 4, in step S9, a fourth etching process is performed to remove another portion of the sacrificial layer in the trench and to expose the etching stop structure in the trench.

Referring to FIG. 1R, and FIG. 4, in step S10, a passivation structure is formed over the backside of the substrate and in the trench.

Referring to FIG. 1S, and FIG. 4, in step S11, an isolation structure is formed over the passivation structure and in the trench.

In some embodiments, after step S6 and before step S7, a hard mask material layer is optionally formed on the backside of the substrate. This hard mask material layer serves to protect the backside of the substrate, as illustrated in FIG. 3A to FIG. 3C.

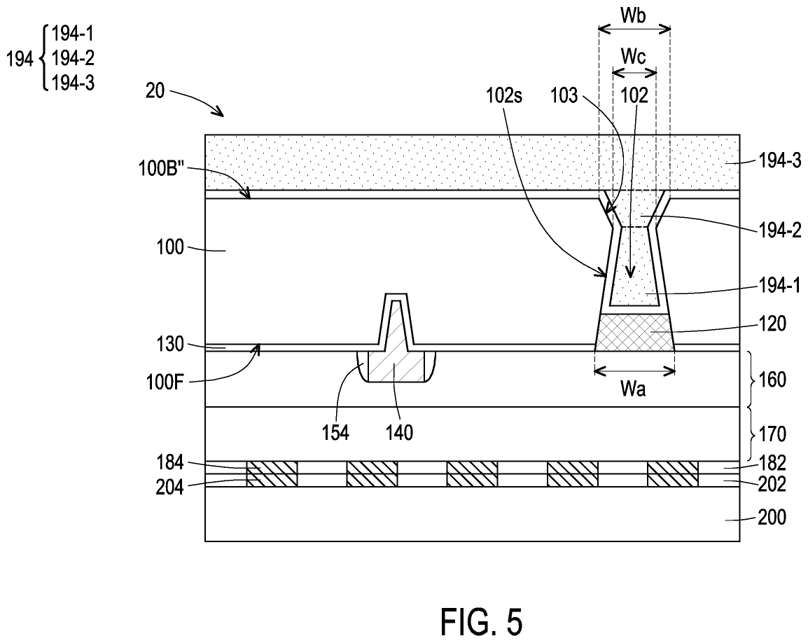

FIG. 5 is a schematic vertical cross-sectional view of a semiconductor device 20 in accordance with various embodiments. It should be noted herein that, in embodiments provided in FIG. 5, element numerals and partial content of the embodiments provided in FIG. 1A to FIG. 1S are followed, the same or similar reference numerals being used to represent the same or similar elements, and description of the same technical content being omitted. For a description of an omitted part, reference may be made to the foregoing embodiment, and the descriptions thereof are omitted herein.

In the semiconductor device 20, the initially formed trench 102 (referring to the step shown in FIG. 1B) on the first side 100F of the semiconductor substrate 100 has a trapezoidal profile. In other words, the initially formed trench 102 is wider on the first side 100F. Consequently, after performing the third etching process E3 on the trapezoidal trench 102 (referring to the step shown in FIG. 1P), the final trench 102 exhibits a wider top and bottom with a narrower middle in the cross-sectional view. In FIG. 5, the width Wa of the trench 102 at the first side 100F and the width Wb of the trench 102 at the second side 100B″ are greater than the width We of the trench 102 at the junction of the first portion 194-1 and the second portion 194-2. In some embodiments, the width Wa may be greater than, less than, or equal to the width Wb. In some embodiments, the trench 102 may include side surfaces with different slopes.

In the semiconductor device 20, a width of the second portion 194-2 decreases as it approaches the first portion 194-1, and a width of the first portion 194-1 decreases as it approaches the second portion 194-2.

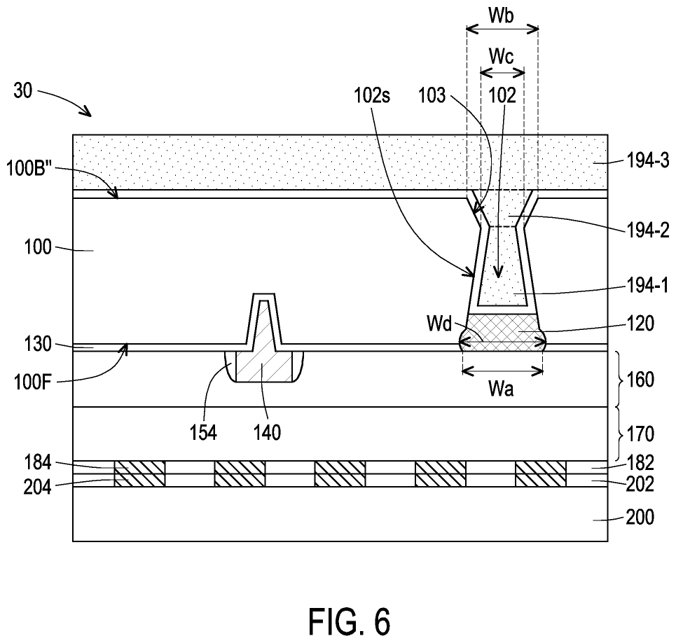

FIG. 6 is a schematic vertical cross-sectional view of a semiconductor device 30 in accordance with various embodiments. It should be noted herein that, in embodiments provided in FIG. 6, element numerals and partial content of the embodiments provided in FIG. 5 are followed, the same or similar reference numerals being used to represent the same or similar elements, and description of the same technical content being omitted. For a description of an omitted part, reference may be made to the foregoing embodiment, and the descriptions thereof are omitted herein.

In the semiconductor device 30, the initially formed trench 102 (referring to the step shown in FIG. 1B) may have a curved sidewall near the first side 100F of the semiconductor substrate 100. Consequently, the etching stop structure 120 subsequently filled into the trench 102 also exhibits a curved sidewall. In this configuration, the widest width Wd of trench 102 is not located at the first side 100F or the second side 100B″, but rather near the curved sidewall adjacent to the first side 100F.

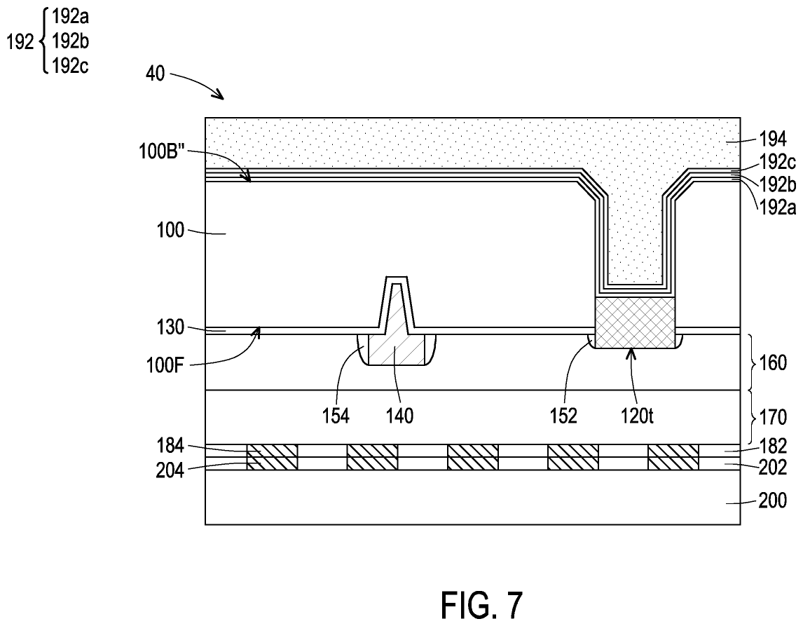

FIG. 7 is a schematic vertical cross-sectional view of a semiconductor device 40 in accordance with various embodiments. It should be noted herein that, in embodiments provided in FIG. 7, element numerals and partial content of the embodiments provided in FIG. 1A to FIG. 1S are followed, the same or similar reference numerals being used to represent the same or similar elements, and description of the same technical content being omitted. For a description of an omitted part, reference may be made to the foregoing embodiment, and the descriptions thereof are omitted herein.

In the semiconductor device 40, the passivation structure between the etching stop structure 120 and the isolation structure 194 has a multi-layered structure, including a first passivation layer 192a, a second passivation layer 192b and a third passivation layer 192c. The first passivation layer 192a is in contact with the etching stop structure 120 and the semiconductor substrate 100, the third passivation layer 192c is in contact with the isolation structure 194, and the second passivation layer 192b is located between the first passivation layer 192a and the third passivation layer 192c. In some embodiments, the first passivation layer 192a, the second passivation layer 192b and the third passivation layer 192c respectively comprise aluminum oxide, hafnium oxide and tantalum oxide.

In an embodiment, a semiconductor device includes a substrate, an etching stop structure, a passivation structure and an isolation structure. The etching stop structure is embedded in a front side of the substrate. The passivation structure is covering a backside of the substrate, and extending from the backside of the substrate to the etching stop structure within a trench of the substrate. The isolation structure is embedded in the trench of the substrate from the backside of the substrate. The passivation structure is located between the etching stop structure and of the isolation structure. The isolation structure has a first sidewall and a second sidewall unparallel to the first sidewall. The first sidewall is located between the second sidewall and a bottom surface of the isolation structure.

In an embodiment, a semiconductor device includes a semiconductor substrate, an etching stop structure, a deep trench isolation (DTI) structure, and a transfer gate. The semiconductor substrate has a first side and a second side opposite to the first side. The etching stop structure is embedded in the first side of the semiconductor substrate. The DTI structure is embedded in the second side of the semiconductor substrate and overlapping with the etching stop structure. The DTI structure includes a first portion with a first sidewall and a second portion with a second sidewall. The first portion is located between the etching stop structure and the second portion, and a slope of the first sidewall is different from a slope of the second sidewall. The transfer gate is located over the first side of the semiconductor substrate.

In an embodiment, a method for fabricating a semiconductor device includes the following steps. A trench is formed from a first side of a substrate. A sacrificial layer is formed in the trench. An etching stop structure is formed over the sacrificial layer in the trench. The substrate is thinned from a second side of the substrate opposite to the first side. A first etching process is performed on the substrate to expose the sacrificial layer from the second side of the substrate. A second etching process is performed to remove a portion of the sacrificial layer in the trench. A third etching process is performed to remove a sharp corner of the substrate around the trench. A fourth etching process is performed to remove another portion of the sacrificial layer in the trench and to expose the etching stop structure in the trench. A passivation structure is formed over the second side of the substrate and in the trench. An isolation structure is formed over the passivation structure and in the trench.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
an etching stop structure, embedded in a front side of the substrate;
a passivation structure, covering a backside of the substrate, and extending from the backside of the substrate to the etching stop structure within a trench of the substrate; and
an isolation structure, embedded in the trench of the substrate from the backside of the substrate, wherein the passivation structure is located between the etching stop structure and of the isolation structure, wherein the isolation structure has a first sidewall and a second sidewall unparallel to the first sidewall, wherein the first sidewall is located between the second sidewall and a bottom surface of the isolation structure.

2. The semiconductor device of claim 1, wherein the etching stop structure is protruding from the front side of the substrate.

3. The semiconductor device of claim 2, further comprising:
a gate electrode, located above the front side of the substrate;
a first spacer, disposed on a sidewall of the etching stop structure; and
a second spacer, disposed on a sidewall of the gate electrode, wherein a height of the first spacer is different from a height of the second spacer.

4. The semiconductor device of claim 1, wherein the isolation structure comprises:
a first portion, having the first sidewall and embedded in the substrate;
a second portion, having the second sidewall and embedded in the substrate, wherein a width of the second portion decreases as it approaches the first portion; and
a third portion, over the backside of the substrate, wherein the second portion is connected between the first portion and the third portion.

5. The semiconductor device of claim 4, wherein a width of the first portion decreases as it approaches the second portion.

6. The semiconductor device of claim 1, wherein the trench has a first side surface and a second side surface respectively facing to the first sidewall and the second sidewall of the isolation structure, and there is an angle between the first side surface and the second side surface.

7. A semiconductor device, comprising:
a semiconductor substrate having a first side and a second side opposite to the first side;
an etching stop structure, embedded in the first side of the semiconductor substrate;
a deep trench isolation (DTI) structure, embedded in the second side of the semiconductor substrate and overlapping with the etching stop structure, wherein the DTI structure comprises a first portion with a first sidewall and a second portion with a second sidewall, wherein the first portion is located between the etching stop structure and the second portion, and a slope of the first sidewall is different from a slope of the second sidewall; and
a transfer gate, located over the first side of the semiconductor substrate.

8. The semiconductor device of claim 7, further comprising:
an insulation layer, disposed between the DTI structure and the etching stop structure, between the first sidewall and the semiconductor substrate and between the second sidewall and the semiconductor substrate.

9. The semiconductor device of claim 7, wherein the etching stop structure comprises a curved sidewall.

10. The semiconductor device of claim 7, wherein the DTI structure is embedded in a trench of the semiconductor substrate, and the semiconductor substrate has a chamfer at a corner of a sidewall of the trench and the second side of the semiconductor substrate.

11. The semiconductor device of claim 7, further comprising:
a first spacer, surrounding the etching stop structure; and
a second spacer, surrounding the transfer gate, wherein a height of the first spacer is different from a height of the second spacer.

12. A method for fabricating a semiconductor device, comprising:
forming a trench from a first side of a substrate;
forming a sacrificial layer in the trench;
forming an etching stop structure over the sacrificial layer in the trench;
thinning the substrate from a second side of the substrate opposite to the first side;
performing a first etching process on the substrate to expose the sacrificial layer from the second side of the substrate;
performing a second etching process to remove a portion of the sacrificial layer in the trench;
performing a third etching process to remove a sharp corner of the substrate around the trench;
performing a fourth etching process to remove another portion of the sacrificial layer in the trench and to expose the etching stop structure in the trench;
forming a passivation structure over the second side of the substrate and in the trench; and
forming an isolation structure over the passivation structure and in the trench.

13. The method of claim 12, further comprising:
forming a gate electrode over the first side of the substrate;
forming a spacer material layer over the gate electrode and the etching stop structure;
etching the spacer material layer to form a first spacer surrounding the etching stop structure and a second spacer surrounding the gate electrode, wherein a height of the first spacer is different from a height of the second spacer;
forming an inter-layer dielectric (ILD) structure over the gate electrode;
forming a redistribution layer over the ILD structure; and
bonding the redistribution layer to an integrated circuit before thinning the substrate from the second side of the substrate opposite to the first side.

14. The method of claim 12, further comprising:
forming a hard mask material layer on the second side of the substrate;
patterning the hard mask material layer by the second etching process to form a hard mask layer exposing the sharp corner of the substrate and the sacrificial layer in the trench; and
removing the hard mask layer and the another portion of the sacrificial layer in the trench together by the fourth etching process.

15. The method of claim 12, wherein the first etching process comprises a combination of a wet etching process and a dry etching process.

16. The method of claim 12, wherein the isolation structure has a first sidewall and a second sidewall unparallel to the first sidewall, wherein the first sidewall is located between the second sidewall and a bottom surface of the isolation structure.

17. The method of claim 12, wherein a chamfer is formed at a corner of a sidewall of the trench and the second side of the substrate by the third etching process, and the passivation structure is formed on the chamfer, the second side of the substrate and the etching stop structure.

18. The method of claim 12, wherein the another portion of the sacrificial layer in the trench protects a portion of a sidewall of the trench during the third etching process.

19. The method of claim 12, wherein 70% to 95% of the sacrificial layer is retained in the trench after the second etching process.

20. The method of claim 12, wherein performing the first etching process on the substrate to form the sharp corner of the substrate surrounding the sacrificial layer.
